(19) United States
(12) Patent Application Publication
(10) Pub. No.: US 2004/0051575 A1
(43) Pub. Date: Mar. 18, 2004

(54) Flip flop, shift register, and operating method thereof

(76) Inventor: Satoshi Machida, Chiba-shi (JP)

Correspondence Address: ADAMS & WILKS, 31st Floor, 50 Broadway, New York, NY, 10004, US

(21) Appl. No.: 10/616,384

(22) Filed: Jul. 9, 2003

(30) Foreign Application Priority Data
Jul. 19, 2002 (JP) 2002-210920

(51) Int. Cl. H03K 3/037

(52) U.S. Cl. 327/218

(57) ABSTRACT

Provided are a flip flop and a shift resistor whose layout areas are small. A data input terminal is connected with a first terminal of a first switching element, and a second terminal of the first switching element is connected with an input terminal of a first inverter element. Further, an output of the first inverter element is inputted to a first terminal of a second switching element, a second terminal of the second switching element is connected with an input terminal of a second inverter element, and an output terminal of the second inverter element is a data output terminal.

### BACKGROUND OF THE INVENTION

1. Field of the Invention

The present invention relates to a flip flop used for general ICs and a shift register composed of a plurality of flip flops which are connected thereto.

2. Description of the Related Art

FIG. 5 shows an example of a conventional flip flop.

This flip flop is composed of transmission gates as a switching elements, inverters, and latch elements. In a general standby state, an S terminal is set to a high state and an SX terminal is set to a low state, so that an M terminal is held in a high state and a QX terminal is held in a low state.

FIG. 6 shows a shift register composed of a plurality of flip flops as described above which are connected in series.

However, there is a problem in that a large number of elements are used for such a flip flop.

Also, in the shift register composed of the plurality of flip flops that are connected in series, signal lines for the S terminal and the SX terminal are required. Therefore, it is necessary to use four signal lines including signal lines for a C terminal and a CX terminal.

Thus, there is a problem in that a layout area is large.

### SUMMARY OF THE INVENTION

A flip flop according to the present invention includes: a first switching element in which a first terminal thereof is connected with a data input terminal; a first inverter element in which an input terminal thereof is connected with a second terminal of the first switching element; a second switching element in which an output of the first inverter element is inputted to a first terminal thereof; and a second inverter element in which an input terminal thereof is connected with the second terminal of the second switching element. Further, the flip flop is characterized in that an output terminal of the second inverter element is a data output terminal.

According to the flip flop of the present invention, a transistor for maintaining a standby state is unnecessary, so that a layout area can be decreased. In addition, in the shift register composed of the plurality of flip flops connected in series, common signal lines for bringing the shift register to the standby state are unnecessary, so that the layout area can be decreased.

### BRIEF DESCRIPTION OF THE DRAWINGS

In the accompanying drawings:

FIG. 1 is a circuit diagram of a flip flop of the present invention;

FIG. 2 shows an example of a circuit for making signals CX and C supplied to the flip flop of the present invention;

FIG. 3 is a timing chart showing operation of the flip flop of the present invention;

FIG. 4 is a circuit diagram of a shift register composed of a plurality of flip flops of the present invention which are connected in series;

FIG. 5 is a circuit diagram of a conventional flip flop; and

FIG. 6 is a circuit diagram of a conventional shift register.

### DETAILED DESCRIPTION OF THE PREFERRED EMBODIMENT

Hereinafter, the present invention will be described with reference to the drawings.

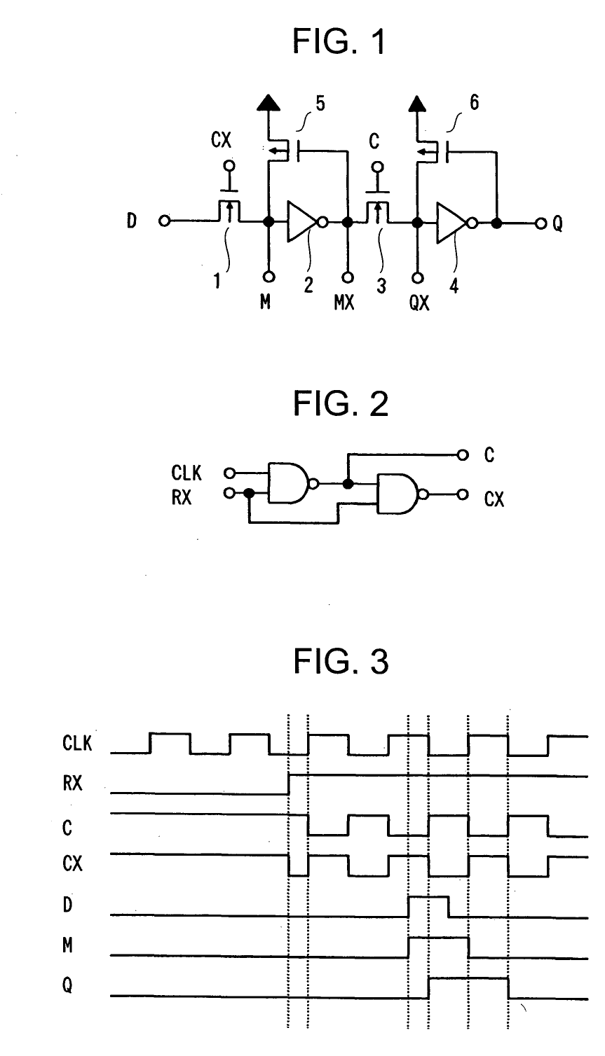

FIG. 1 is a circuit diagram of a flip flop of the present invention.

This flip flop includes an NMOS transistor 1 as a first switching element, a first inverter 2, an NMOS transistor 3 as a second switching element, a second inverter 4, and transistors 5 and 6 as latch elements. Because the flip flop is composed of two switching elements, two inverters, and two transistors, the number of elements can be made small. In addition, if potentials on an M terminal and a QX terminal are stable, the latch elements 5 and 6 can be omitted.

FIG. 2 shows an example of a circuit for producing signals CX and C that are inputted to the gates of the switching elements 1 and 3 in the flip flop. According to this circuit, when RX is in a low state, the signals C and CX always become a high state.

FIG. 3 is a timing chart showing operations of the circuit shown in FIGS. 1 and 2.

When RX is in the low state, the signals C and CX are at the high level, so that the switching elements 1 and 3 are turned ON. Therefore, all potentials in the flip flop are fixed. When D is in the low state, M and Q are fixed to the low state and MX and QX are fixed to a high state. When D is in the high state, M and Q are fixed to the high state and MX and QX are fixed to the low state. In other words, because there is no unsteady potential, a reliable standby state is obtained. When RX becomes the high state, the signal C becomes an inverted pulse of CLK and the signal CX becomes a pulse in phase with CLK, so that data transfer is possible.

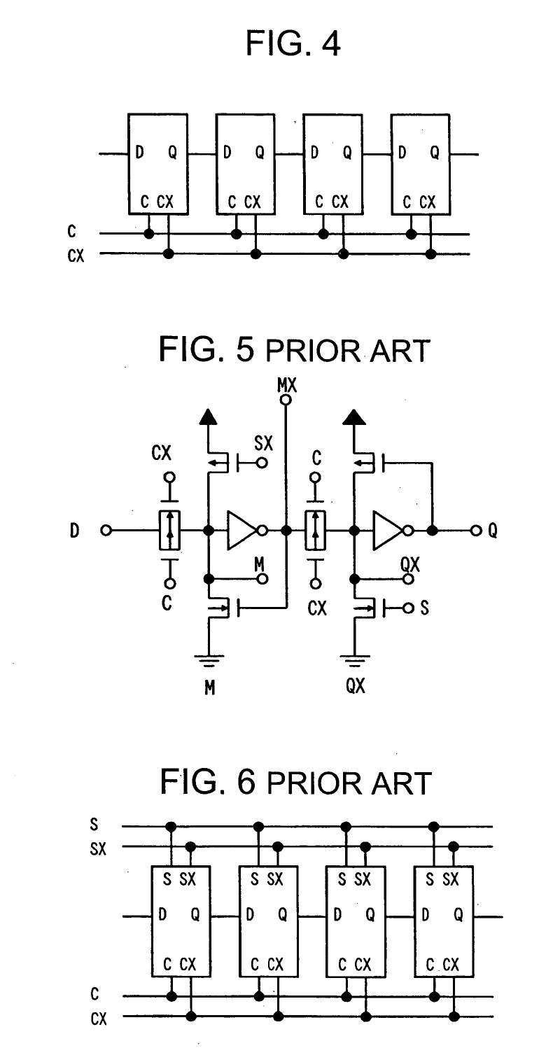

FIG. 4 is a circuit diagram of a shift register composed of a plurality of flip flops of the present invention which are connected in series. This shift register is composed of the flip flops shown in FIG. 1 and the signals C and CX are supplied from the circuit shown in FIG. 2. Accordingly, in the standby state, all Q outputs are fixed to the low state or the high state.

Common signal lines of the shift register are provided for only the signals C and CX, and common signal lines for bringing the shift register to the standby state are unnecessary. In other words, common lines composing the shift register are a power source line and two lines for the signals C and CX, so that the layout area can be decreased.

In the above description, the first switching element or the second switching element may be a transmission gate or a PMOS transistor.

As described above, according to the flip flop of the present invention, a transistor for maintaining to a standby state is unnecessary, so that a layout area can be decreased. In addition, in the shift register of the present invention, common signal lines for bringing the shift register to the standby state are unnecessary, so that the layout area can be decreased.

What is claimed is:

1. A flip flop comprising:
a first switching element in which a first terminal thereof is connected with a data input terminal;
a first inverter element in which an input terminal thereof is connected with a second terminal of the first switching element;
a second switching element in which an output of the first inverter element is inputted to a first terminal thereof; and
a second inverter element in which an input terminal thereof is connected with a second terminal of the second switching element,
wherein an output terminal of the second inverter element is a data output terminal.

2. A flip flop according to claim 1; further comprising a first MOS transistor and a second MOS transistor,
wherein the output of the first inverter element is inputted to a gate terminal of the first MOS transistor and a drain of the first MOS transistor is connected with the input terminal of the first inverter element, and
wherein the output of the second inverter element is inputted to a gate terminal of the second MOS transistor and a drain of the second MOS transistor is connected with the input terminal of the second inverter element.

3. A flip flop according to claim 2; wherein the first switching element is composed of a first NMOS transistor, a first control signal (CX) is inputted to a gate of the first NMOS transistor, the second switching element is composed of a second NMOS transistor, and a second control signal (C) is inputted to a gate of the second NMOS transistor.
